(19) United States
(12) Patent Application Publication
(10) Pub. No.: US 2011/0110436 A1
(43) Pub. Date: May 12, 2011

(54) Flexible Sub-Stream Referencing Within a Transport Data Stream

(76) Inventors: Thomas Schierl, Berlin (DE); Cornelius Hellge, Berlin (DE); Karsten Grueneberg, Berlin (DE)

(21) Appl. No.: 12/989,135

(22) PCT Filed: Dec. 3, 2008
(86) PCT No.: PCT/EP2008/010258

§ 371 Date: Jan. 5, 2011

(30) Foreign Application Priority Data
Apr. 25, 2008 (EP) PCT EP2008 003384

(51) Int. Cl. H04N 7/26; H03K 9/00; H04N 7/24

(52) U.S. Cl. 375/240.26; 375/316; 375/E07.012; 375/E07.2

(57) ABSTRACT

A representation of a video sequence having a first data stream comprising first data portions, the first data portions comprising first timing information and a second data stream, the second data stream comprising a second data portion having second timing information, may be derived. association information is associated to a second data portion of the second data stream, the association information indicating a predetermined first data portion of the first data stream. A transport stream comprising the first and the second data stream as the representation of the video sequence is generated.

### CROSS-REFERENCE TO RELATED APPLICATION

This application is a U.S. National Phase entry of PCT/EP2008/010258 filed Dec. 3, 2008, and claims priority to International Patent Application No. PCT/EP2008/003384 filed 25 Apr. 2008, each of which is incorporated herein by references hereto.

### BACKGROUND OF THE INVENTION

Embodiments of the present invention relate to schemes to flexibly reference individual data portions of different sub-streams of a transport data stream containing two or more sub-streams. In particular, several embodiments relate to a method and an apparatus to identify reference data portions containing information about reference pictures needed for the decoding of a video stream of a higher layer of a scalable video stream when video streams with different timing properties are combined into one single transport stream.

Applications in which multiple data streams are combined within one transport stream are numerous. This combination or multiplexing of the different data streams is often needed in order to be able to transmit the full information using only one single physical transport channel to transmit the generated transport stream.

For example, in an MPEG-2 transport stream used for satellite transmission of multiple video programs, each video program is contained within one elementary stream. That is, data fractions of one particular elementary stream (which are packetized in so-called PES packets) are interleaved with data fractions of other elementary streams. Moreover, different elementary streams or sub-streams may belong to one single program as, for example, the program may be transmitted using one audio elementary stream and one separate video elementary stream. The audio and the video elementary streams are, therefore, dependent on each other. When using scalable video codes (SVC), the interdependencies can be even more complicated, as a video of the backwards-compatible AVC (Advanced Video Codec) base layer (H.264/AVC) may then be enhanced by adding additional information, so-called SVC sub-bitstreams, which enhance the quality of the AVC base layer in terms of fidelity, spatial resolution and/or temporal resolution. That is, in the enhancement layers (the additional SVC sub-bitstreams), additional information for a video frame may be transmitted in order to enhance its perceptive quality.

For the reconstruction, all information belonging to one single video frame is collected from the different streams prior to a decoding of the respective video frame. The information contained within different streams that belongs to one single frame is called a NAL unit (Network Abstraction Layer Unit). The information belonging to one single picture may even be transmitted over different transmission channels. For example, one separate physical channel may be used for each sub-bitstream. However, the different data packets of the individual sub-bitstreams depend on one another. The dependency is often signaled by one specific syntax element (dependency_ID: DID) of the bitstream syntax. That is, the SVC sub-bitstreams (differing in the H.264/SVC NAL unit header syntax element: DID), which enhance the AVC base layer or one lower sub-bitstream in at least one of the possible scalability dimensions fidelity, spatial or temporal resolution, are transported in the transport stream with different PID numbers (Packet Identifier). They are, so to say, transported in the same way as different media types (e.g. audio or video) for the same program would be transported. The presence of these sub-streams is defined in a transport stream packet header associated to the transport stream.

However, for reconstructing and decoding the images and the associated audio data, the different media types have to be synchronized prior to, or after, decoding. The synchronization after decoding is often achieved by the transmission of so-called “presentation timestamps” (PTS) indicating the actual output/presentation time tp of a video frame or an audio frame, respectively. If a decoded picture buffer (DPB) is used to temporarily store a decoded picture (frame) of a transported video stream after decoding, the presentation timestamp tp therefore indicates the removal of the decoded picture from the respective buffer. As different frame types may be used, such as, for example, p-type (predictive) and b-type (bi-directional) frames, the video frames do not necessarily have to be decoded in the order of their presentation. Therefore, so-called “decoding timestamps” are normally transmitted, which indicate the latest possible time of decoding of a frame in order to guarantee that the full information is present for the subsequent frames.

When the received information of the transport stream is buffered within an elementary stream buffer (EB), the decoding timestamp (DTS) indicates the latest possible time of removal of the information in question from the elementary stream buffer (EB). The conventional decoding process may, therefore, be defined in terms of a hypothetical buffering model (T-STD) for the system layer and a buffering model (HRD) for the video layer. The system layer is understood to be the transport layer, that is, a precise timing of the multiplexing and de-multiplexing needed in order to provide different program streams or elementary streams within one single transport stream is vital. The video layer is understood to be the packetizing and referencing information needed by the video codec used. The information of the data packets of the video layer are again packetized and combined by the system layer in order to allow for a serial transmission of the transport channel.

One example of a hypothetical buffering model used by MPEG-2 video transmission with a single transport channel is given in FIG. 1. The timestamps of the video layer and the timestamps of the system layer (indicated in the PES header) shall indicate the same time instant. If, however, the clocking frequency of the video layer and the system layer differs (as it is normally the case), the times shall be equal within the minimum tolerance given by the different clocks used by the two different buffer models (STD and HRD).

In the model described by FIG. 1, a transport stream data packet 2 arriving at a receiver at time instant t(i) is de-multiplexed from the transport stream into different independent streams 4a-4d, wherein the different streams are distinguished by different PID numbers present within each transport stream packet header.

The transport stream data packets are stored in a transport buffer 6 (TB) and then transferred to a multiplexing buffer 8 (MB). The transfer from the transport buffer TB to the multiplexing buffer MB may be performed with a fixed rate.

Prior to delivering the plain video data to a video decoder, the additional information added by the system layer (transport layer), that is, the PES header is removed. This can be performed before transferring the data to an elementary stream buffer 10 (EB). That is, the removed corresponding timing information as, for example, the decoding timestamp td and/or the presentation time stamp tp should be stored as side information for further processing when the data is transferred from MB to EB. In order to allow for a in-order reconstruction, the data of access unit A(j) (the data corresponding to one particular frame) is removed no later than td(j) from the elementary stream buffer 10, as indicated by the decoding timestamp carried in the PES header. Again, it may be emphasized that the decoding timestamp of the system layer should be equal to the decoding timestamp in the video layer, as the decoding timestamp of the video layer (indicated by so-called SEI messages for each access unit A(j)) are not sent in plain text within the video bitstream. Therefore, utilizing the decoding timestamps of the video layer would need further decoding of the video stream and would, therefore, make a simple and efficient multiplexed implementation unfeasible.

A decoder 12 decodes the plain video content in order to provide a decoded picture, which is stored in a decoded picture buffer 14. As indicated above, the presentation timestamp provided by the video codec is used to control the presentation, that is the removal of the content stored in the decoded picture buffer 14 (DPB).

As previously illustrated, the current standard for the transport of scalable video codes (SVC) defines the transport of the sub-bitstreams as elementary streams having transport stream packets with different PID numbers. This needs additional reordering of the elementary stream data contained in the transport stream packets to derive the individual access units representing a single frame.

The reordering scheme is illustrated in FIG. 2. The de-multiplexer 4 de-multiplexes packets having different PID numbers into a separate buffer chains 20a to 20c. That is, when an SVC video stream is transmitted, parts of an identical access unit transported in different sub-streams are provided to different dependency-representation buffers (DRBₙ) of different buffer chains 20a to 20c. Finally, the should be provided to a common elementary stream buffer 10 (EB), buffering the data before being provided to the decoder 22. The decoded picture is then stored in a common decoded picture buffer 24.

In other words, parts of the same access unit in the different sub-bitstreams (which are also called dependency representations DR) are preliminarily stored in dependency representation buffers (DRB) until they can be delivered into the elementary stream buffer 10 (EB) for removal. A sub-bitstream with the highest syntax element “dependency_ID” (DID), which is indicated within the NAL unit header, comprises all access units or parts of the access units (that is of the dependency representations DR) with the highest frame rate. For example, a sub-stream being identified by dependency_ID=2 may contain image information encoded with a frame rate of 50 Hz, whereas the sub-stream with dependency_ID=1 may contain information for a frame rate of 25 Hz.

According to the present implementations, all dependency representations of the sub-bitstreams with identical decoding times td are delivered to the decoder as one particular access unit of the dependency representation with the highest available value of DID. That is, when the dependency representation with DID=2 is decoded, information of dependency representations with DID=1 and DID=0 are considered. The access unit is formed using all data packets of the three layers which have an identical decoding timestamp td. The order in which the different dependency representations are provided to the decoder is defined by the DID of the sub-streams considered. The de-multiplexing and reordering is performed as indicated in FIG. 2. An access unit is abbreviated with A. DBP indicates a decoded picture buffer and DR indicates a dependency representation. The dependency representations are temporarily stored in dependency representation buffers DRB and the re-multiplexed stream is stored in an elementary stream buffer EB prior to the delivery to the decoder 22. MB denotes multiplexing buffers and PID denotes the program ID of each individual sub-stream. TB indicates the transport buffers and td indicates the coding timestamp.

However, the previously-described approach assumes that the same timing information is present within all dependency representations of the sub-bitstreams associated to the same access unit (frame). This may, however, not be true or achievable with SVC content, neither for the decoding timestamps nor for the presentation timestamps supported by SVC timings.

This problem may arise, since Annex A of the H.264/AVC standard defines several different profiles and levels. Generally, a profile defines the features that a decoder compliant with that particular profile supports. The levels define the size of the different buffers within the decoder. Furthermore, so-called “Hypothetical Reference Decoders” (HRD) are defined as a model simulating the desired behavior of the decoder, especially of the associated buffers at the selected level. The HRD model is also used at the encoder in order to assure that the timing information introduced into the encoded video stream by the encoder does not break the constrains of the HRD model and, therewith, the buffer size at the decoder. This would, consequently, make decoding with a standard compliant decoder impossible. A SVC stream may support different levels within different sub-streams. That is, the SVC extension to video coding provides the possibility to create different sub-streams with different timing information. For example, different frame rates may be encoded within the individual sub-streams of an SVC video stream.

The scalable extension of H.264/AVC (SVC) allows for encoding scalable streams with different frame rates in each sub-stream. The frame-rates can be a multiple of each other, e.g. base layer 15 Hz and temporal enhancement layer 30 Hz. Furthermore, SVC also allows having a shifted frame-rate ratio between the sub-streams, for instance the base layer provides 25 Hz and the enhancement layer 30 Hz. Note, that the SVC extended ITU-T H.222.0 standard shall (system-layer) be able to support such encoding structures.

FIG. 3 gives one example for different frame rates within two sub-streams of a transport video stream. The base layer (the first data stream) 40 may have a frame rate of 30 Hz and the temporal enhancement layer 42 of channel 2 (the second data stream) may have a frame rate of 50 Hz. For the base layer, the timing information (DTS and PTS) in the PES header of the transport stream or the timing in the SEIs of the video stream are sufficient to decode the lower frame-rate of the base layer.

If the complete information of a video frame was included into the data packets of the enhancement layer, the timing information in the PES headers or in the in-stream SEIs in the enhancement layer were also sufficient for decoding the higher frame rate. As, however, MPEG provides for complex referencing mechanisms by introducing p-frames or i-frames, data packets of the enhancement layer may utilize data packets of the base layer as reference frames. That is, a frame decoded from the enhancement layer utilizes information on frames provided by the base layer. This situation is illustrated in FIG. 3 where the two illustrated data portions 40a and 40b of the base layer 40 have decoding timestamps corresponding to the presentation time in order to fulfill the requirements of the HRD-model for the rather slow base-layer decoders. The information needed for an enhancement layer decoder in order to fully decode a complete frame is given by data blocks 44a to 44d.

The first frame 44a to be reconstructed with a higher frame rate needs the complete information of the first frame 40a of the base layer and of the first three data portions 42a of the enhancement layer. The second frame 44b to be decoded with a higher frame rate needs the complete information of the second frame 40b of the base layer and of the data portions 42b of the enhancement layer.

A conventional decoder would combine all NAL units of the base and enhancement layers having the same decoding timestamp DTS or presentation timestamp PTS. The time of removal of the generated access unit AU from the elementary buffer would be given by the DTS of the highest layer (the second data stream). However, the association according to the DTS or PTS values within the different layers is no longer possible, since the values of the corresponding data packets differ. In order to maintain the association according to the PTS or DTS values possible, the second frame 40b of the base layer could theoretically be given a decoding timestamp value as indicated by the hypothetical frame 40c of the base layer. Then, however, a decoder compliant with the base layer standard only (the HRD model corresponding to the base layer) would no longer be able to decode even the base layer, since the associated buffers are too small or the processing power is too slow to decode the two subsequent frames with the decreased decoding time offset.

In other words, conventional technologies make it impossible to flexibly use information of a preceding NAL unit (frame 40b) in a lower layer as a reference frame for decoding information of a higher layer. However, this flexibility may be needed, especially when transporting video with different frame rates having uneven ratios within as different layers of an SVC stream. One important example may, for example, be a scalable video stream having a frame rate of 24 frames/sec (as used in cinema productions) in the enhancement layer and 20 frames/sec in the base layer. In such a scenario, it may be extremely bit saving to code the first frame of the enhancement layer as a p-frame depending on an i-frame 0 of the base layer. The frames of these two layers would, however, obviously have different timestamps. Appropriate de-multiplexing and reordering to provide a sequence of frames in the right order for a subsequent decoder would not be possible using conventional techniques and the existing transport stream mechanisms described in the previous paragraphs. Since both layers contain different timing information for different frame rates, the MPEG transport stream standard and other known bit stream transport mechanisms for the transport of scalable video or interdependent data streams do not provide the needed flexibility that allows to define or to reference the corresponding NAL units or data portions of the same pictures in a different layer.

### SUMMARY

According to an embodiment, a method for deriving a decoding strategy for a second data portion depending on the reference data portion, the second data portion being part of a second data stream of a transport stream, the transport stream having the second data stream and a first data stream having first data portions, the first data portions having first timing information and the second data portion of the second data stream having second timing information and association information indicating a predetermined first data portion of the first data stream may have the step of deriving the decoding strategy for the second data portion using the second timing information as an indication for a processing time for the second data portion and the referenced predetermined first data portion of the first data stream as the reference data portion by using the second timing information as an indication for a processing time for the reference data portion, such that the second data portion is processed after the referenced predetermined first data portion of the first data stream.

According to another embodiment, a decoding strategy generator for a second data portion depending on the reference data portion, the second data portion being part of a second data stream of a transport stream, the transport stream having the second data stream and a first data stream having first data portions, the first data portions having first timing information and the second data portion of the second data stream having second timing information and association information indicating a predetermined first data portion of the first data stream may have a reference information generator adapted to derive the reference data portion for the second data portion using the predetermined first data portion of the first data stream; and a strategy generator adapted to derive the decoding strategy for the second data portion, using the second timing information as indication for a processing time for the second data portion, the reference data portion derived by the reference information generator, and using the second timing information as an indication for a processing time for the reference data portion, such that the second data portion is processed after the predetermined first data portion of the first data stream.

According to another embodiment, a method for deriving a processing schedule for a second data portion depending on the reference data portion, the second data portion being part of a second data stream of a transport stream, the transport stream having the second data stream and a first data stream having first data portions, the first data portions having first timing information and the second data portion of the second data stream having second timing information and association information indicating a predetermined first data portion of the first data stream may have the steps of deriving the processing schedule having a processing order such that the second data portion is processed after the predetermined first data portion of the first data stream; and using the second timing information as an indication for a processing time for the reference data portion.

According to another embodiment, a data packet scheduler, adapted to generate a processing schedule for a second data portion depending on a reference data portion, the second data portion being part of a second data stream of a transport stream, the transport stream having the second data stream and a first data stream having first data portions, the first data portions having first timing information and the second data portion of the second data stream having second timing information and association information indicating a predetermined first data portion of the first data stream may have a process order generator adapted to generate a processing schedule having a processing order such that the second data portion is processed after the predetermined first data portion of the first data stream.

According to another embodiment, a method for deriving a decoding strategy for a second data portion depending on a reference data portion, the second data portion being part of a second data stream of a transport stream, the transport stream having the second data stream and a first data stream having first data portions, the first data portions having first timing information and the second data portion having second timing information and association information indicating a predetermined first data portion of the first data stream may have the steps of deriving the decoding strategy for the second data portion using the second timing information as an indication for a processing time for the second data portion and the referenced predetermined first data portion of the first data stream as the reference data portion; wherein the association information of the second data portion is view information indicating one of possible different views within a scalable video data stream.

According to another embodiment, a method for deriving a decoding strategy for a second data portion associated to an encoded video frame of a second layer of a scalable video data stream, the second data portion depending on a reference data portion, the second data portion being part of a second data stream of a transport stream, the transport stream having the second data stream and a first data stream having first data portions associated to encoded video frames of a first layer of a layered video data stream, the first data portions having first timing information and the second data portion having second timing information and association information indicating a predetermined first data portion of the first data stream may have the steps of associating the second data portion with the first predetermined data portion using either a decoding time stamp and a view information or a presentation time stamp and a view information of the first predetermined data portion as the association information, the decoding time stamp indicating a processing time of the first predetermined data portion within the first layer of the scalable video data stream, the view information indicating one of possible different views within the scalable video data stream, the presentation time stamp indicating a presentation time of the first predetermined data portion within the first layer of the scalable video data stream; and deriving the decoding strategy for the second data portion using the second timing information as an indication for a processing time for the second data portion and the referenced predetermined first data portion of the first data stream as the reference data portion.

According to another embodiment, a decoding strategy generator for a second data portion depending on a reference data portion, the second data portion being part of a second data stream of a transport stream, the transport stream having the second data stream and a first data stream having first data portions, the first data portions having first timing information and the second data portion having second timing information and association information indicating a predetermined first data portion of the first data stream may have a reference information generator adapted to derive the reference data portion for the second data portion using the predetermined first data portion of the first data stream; a strategy generator adapted to derive the decoding strategy for the second data portion using the second timing information as indication for a processing time for the second data portion and the reference data portion derived by the reference information generator, wherein the association information of the second data portion is view information indicating one of possible different views within a scalable video data stream.

According to another embodiment, a decoding strategy generator for a second data portion associated to an encoded video frame of a second layer of a scalable video data stream, the second data portion depending on a reference data portion, the second data portion being part of a second data stream of a transport stream, the transport stream having the second data stream and a first data stream having first data portions associated to encoded video frames of a first layer of a layered video data stream, the first data portions having first timing information and the second data portion having second timing information and association information indicating a predetermined first data portion of the first data stream may have a reference information generator adapted to derive the reference data portion for the second data portion using either a decoding time stamp and a view information or a presentation time stamp and a view information of the first predetermined data portion as the association information, the decoding time stamp indicating a processing time of the first predetermined data portion within the first layer of the scalable video data stream, the view information indicating one of possible different views within the scalable video data stream, the presentation time stamp indicating a presentation time of the first predetermined data portion within the first layer of the scalable video data stream; and a strategy generator adapted to derive the decoding strategy for the second data portion using the second timing information as indication for a processing time for the second data portion and the reference data portion derived by the reference information generator.

According to another embodiment, a computer program may have a program code for performing, when running on a computer, a method according to the above-mentioned methods.

According to some embodiments of the present invention, this possibility is provided by methods for deriving a decoding or association strategy for data portions belonging to first and second data streams within a transport stream. The different data streams contain different timing informations, the timing informations being defined such that the relative times within one single data stream are consistent. According to some embodiments of the present invention, the association between data portions of different data streams is achieved by including association information into a second data stream, which needs to reference data portions of a first data stream. According to some embodiments, the association information references one of the already-existing data fields of the data packets of the first data stream. Thus, individual packets within the first data stream can be unambiguously referenced by data packets of the second data stream.

According to further embodiments of the present invention, the information of the first data portions referenced by the data portions of the second data stream is the timing information of the data portions within the first data stream. According to further embodiments, other unambiguous information of the first data portions of the first data stream are referenced, such as, for example, continuous packet ID numbers, or the like.

According to further embodiments of the present invention, no additional data is introduced into the data portions of the second data stream while already-existent data fields are utilized differently in order to include the association information. That is, for example, data fields reserved for timing information in the second data stream may be utilized to enclose the additional association information allowing for an unambiguous reference to data portions of different data streams.

In general terms, some embodiments of the invention also provide the possibility of generating a video data representation comprising a first and a second data stream in which a flexible referencing between the data portions of the different data streams within the transport stream is feasible.

### BRIEF DESCRIPTION OF THE DRAWINGS

Several embodiments of the present invention will, in the following, be described referencing the enclosed Figs., showing:

FIG. 1 an example of transport stream de-multiplexing;

FIG. 2 an example of SVC-transport stream de-multiplexing;

FIG. 3 an example of a SVC transport stream;

FIG. 4 an embodiment of a method for generating a representation of a transport stream;

FIG. 5a further embodiment of a method for generating a representation of a transport stream;

FIG. 6a an embodiment of a method for deriving a decoding strategy;

FIG. 6b a further embodiment of a method for deriving a decoding strategy

FIG. 7 an example of a transport stream syntax;

FIG. 8a further example of a transport stream syntax;

FIG. 9 an embodiment of a decoding strategy generator; and

FIG. 10 an embodiment of a Data packet scheduler.

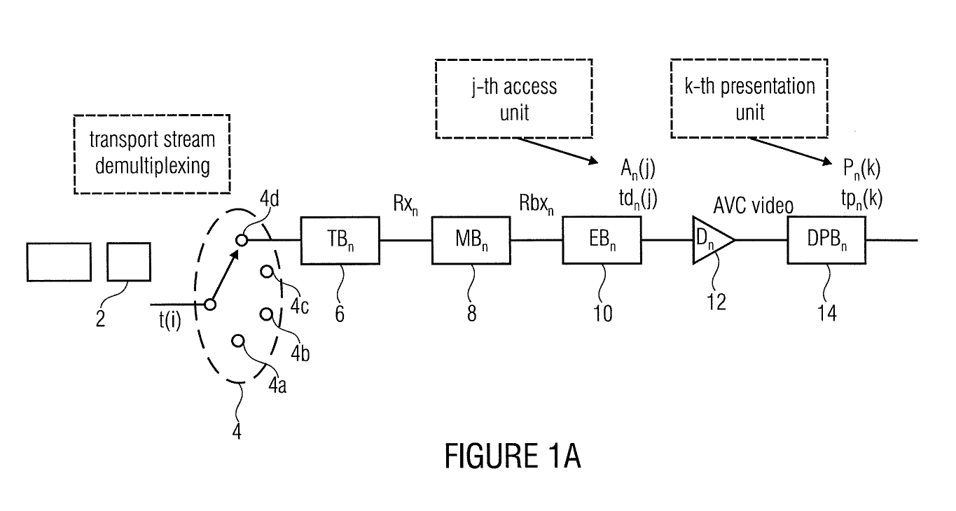

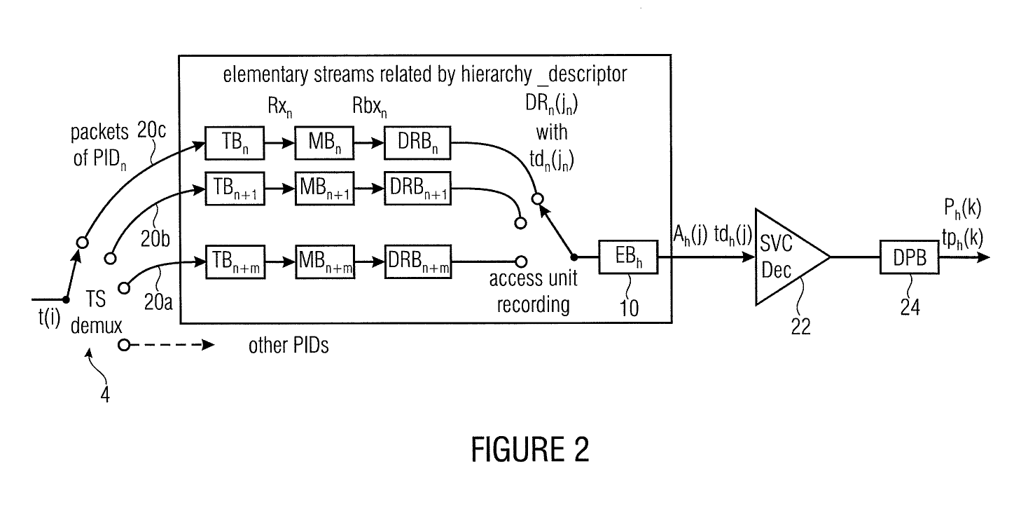

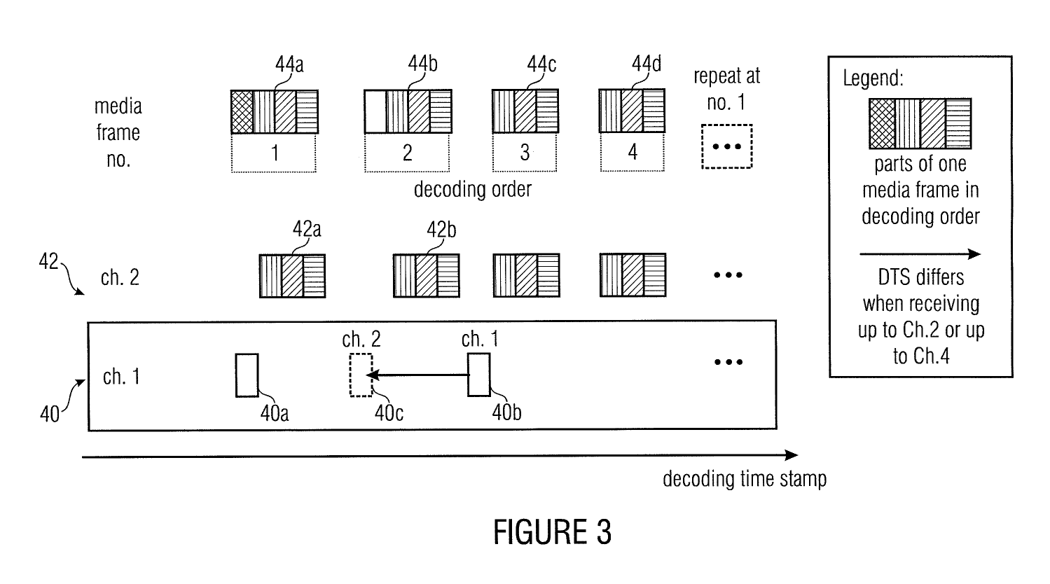

### DETAILED DESCRIPTION OF THE INVENTION

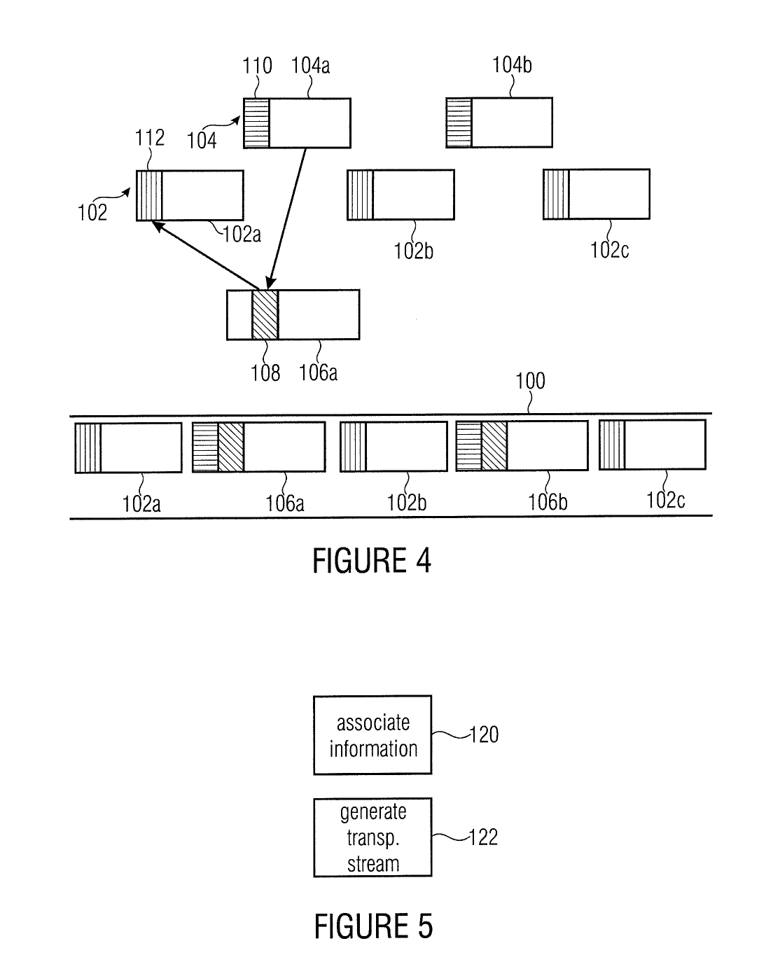

FIG. 4 describes a possible implementation of an inventive method to generate a representation of a video sequence within a transport data stream 100. A first data stream 102 having first data portions 102a to 102c and a second data stream 104 having second data portions 104a and 104b are combined in order to generate the transport data stream 100. Association information is generated, which associates a predetermined first data portion of the first data stream 102 to a second data portion 106 of the second data stream. In the example of FIG. 4, the association is achieved by embedding the association information 108 into the second data portion 104a. In the embodiment illustrated in FIG. 4, the association information 108 references first timing information 112 of the first data portion 102a, for example, by including a pointer or copying the timing information as the association information. It goes without saying that further embodiments may utilize other association information, such as, for example, unique header ID numbers, MPEG stream frame numbers or the like.

A transport stream, which comprises the first data portion 102a and the second data portion 106a may then be generated by multiplexing the data portions in the order of their original timing information.

Instead of introducing the association information as new data fields requiring additional bit space, already-existing data fields, such as, for example, the data field containing the second timing information 110, may be utilized to receive the association information.

FIG. 5 briefly summarizes an embodiment of a method for generating a representation of a video sequence having a first data stream comprising first data portions, the first data portions having first timing information and a second data stream comprising second data portions, the second data portions having second timing information. In an association step 120, association information is associated to a second data portion of the second data stream, the association information indicating a predetermined first data portion of the first data stream.

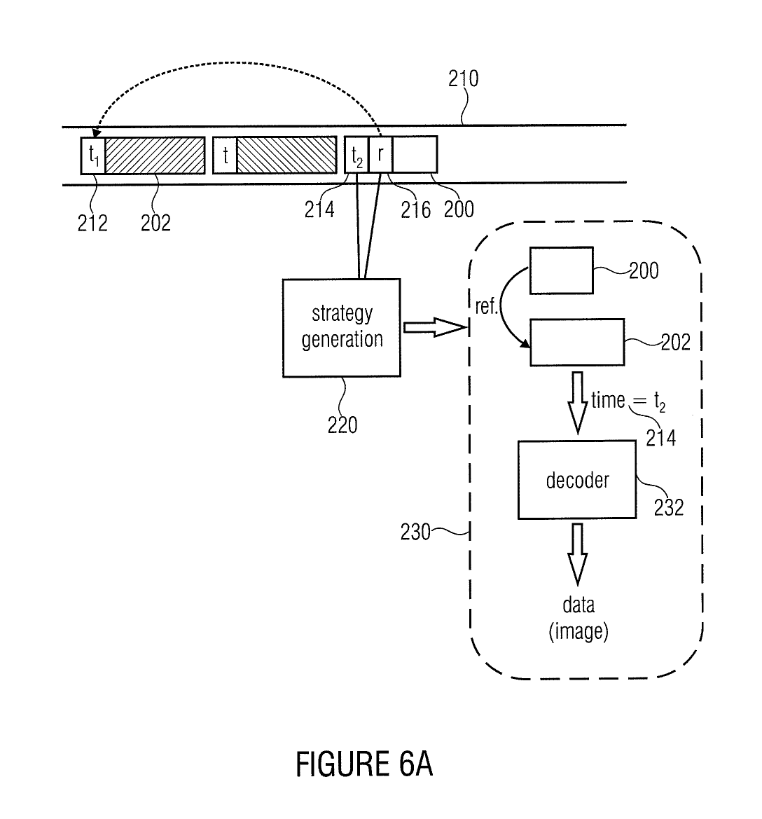

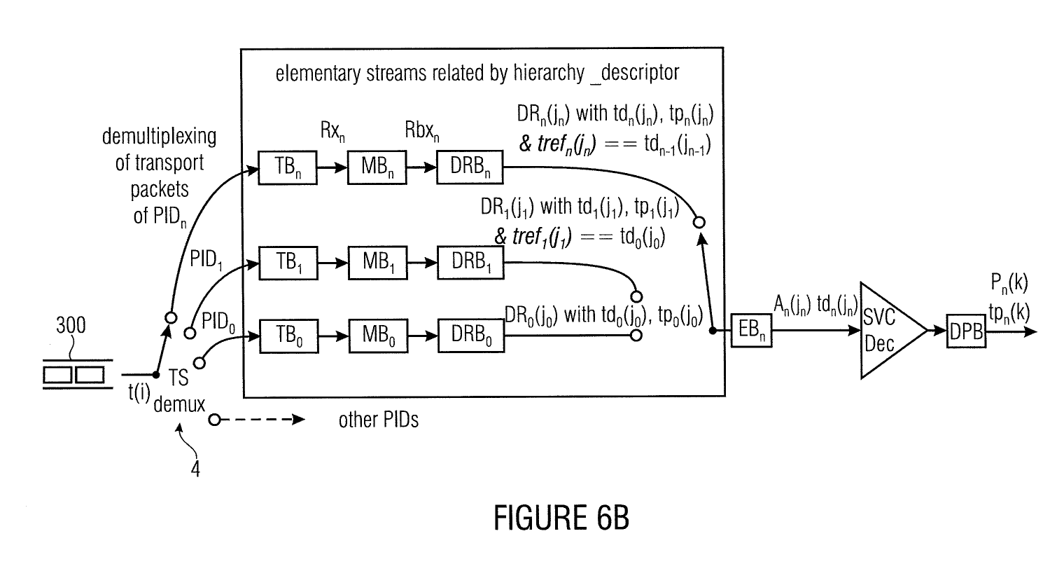

On the decoder side, a decoding strategy may be derived for the generated transport stream 210 as illustrated in FIG. 6a. FIG. 6a illustrates the general concept of the deriving of a decoding strategy for a second data portion 200 depending on a reference data portion 402, the second data portion 200 being part of a second data stream of a transport stream 210, the transport stream comprising a first data stream and a second data stream, the first data portion 202 of the first data stream comprising first timing information 212 and the second data portion 200 of the second data stream comprising second timing information 214 as well as association information 216 indicating a predetermined first data portion 202 of the first data stream. In particular, the association information comprises the first timing information 212 or a reference or pointer to the first timing information 212, thus allowing to unambiguously identify the first data portion 202 within the first data stream.

The decoding strategy for the second data portion 200 is derived using the second timing information 214 as the indication for a processing time (the decoding time or the presentation time) for the second data portion and the referenced first data portion 202 of the first data stream as a reference data portion. That is, once the decoding strategy is derived in a strategy generation step 220, the data portions may be furthermore processed or decoded (in case of video data) by a subsequent decoding method 230. As the second timing information 214 is used as an indication for the processing time t₂ and as the particular reference data portion is known, the decoder can be provided with data portions in the correct order at the right time. That is, the data content corresponding to the first data portion 202 is provided to the decoder first, followed by the data content corresponding to the second data portion 200. The time instant at which both data contents are provided to the decoder 232 is given by the second timing information 214 of the second data portion 200.

Once the decoding strategy is derived, the first data portion may be processed before the second data portion. Processing may in one embodiment mean that the first data portion is accessed prior to the second data portion. In a further embodiment, accessing may comprise the extraction of information needed to decode the second data portion in a subsequent decoder. This may, for example, be the side-information associated to the video stream.

In the following paragraphs, a particular embodiment is described by applying the inventive concept of flexible referencing of data portions to the MPEG transport stream standard (ITU-T Rec. H.222.0|ISO/IEC 13818-1: 2007 FPDAM3.2 (SVC Extensions), Antalya, Turkey, January 2008: [3] ITU-T Rec. H.264 200×4th Edition (SVC)|ISO/IEC 14496-10: 200X 4th edition (SVC)).

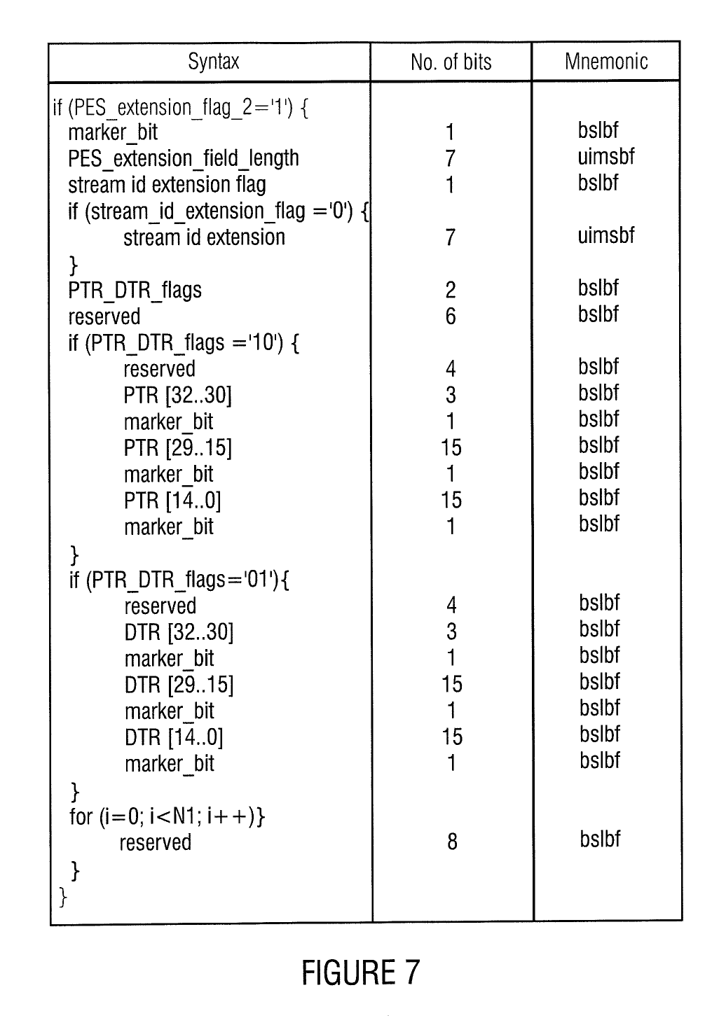

As previously summarized, embodiments of the present invention may contain, or add, additional information for identifying timestamps in the sub-streams (data streams) with lower DID values (for example, the first data stream of a transport stream comprising two data streams). The timestamp of the reordered access unit A(j) is given by the sub-stream with the higher value of DID (the second data stream) or with the highest DID when more than two data streams are present. While the timestamps of the sub-stream with the highest DID of the system layer may be used for decoding and/or output timing, a reordering may be achieved by additional timing information tref indicating the corresponding dependency representation in the sub-stream with another (e.g. the next lower) value of DID. This procedure is illustrated in FIG. 7. In some embodiments, the additional information may be carried in an additional data field, e.g. in the SVC dependency representation delimiter or, for example, as an extension in the PES header. Alternatively, it may be carried in existing timing information fields (e.g. the PES header fields) when it is additionally signaled that the content of the respective data fields shall be used alternatively. In the embodiment tailored to the MPEG 2 transport stream that is illustrated in FIG. 6b, the reordering may be performed as detailed below. FIG. 6b shows multiple structures whose functionalities are described by the following abbreviations:
Aₙ(j)=j^{th} access unit of sub-bitstream n is decoded at tdₙ(jₙ), where n==0 indicates the base layer
DIDₙ=NAL unit header syntax element dependency_id in sub-bitstream n
DPBₙ=decoded picture buffer of sub-bitstream
DRₙ(jₙ)=jₙ^{th} dependency representation in sub-bitstream n
DRBₙ=dependency representation buffer of sub-bitstream n
EBₙ=elementary stream buffer of sub-bitstream n
MBₙ=multiplexing buffer of sub-bitstream n
PIDₙ=program ID of sub-bitstream n in the transport stream
TBₙ=transport buffer of sub-bitstream n
tdₙ(jₙ)=decoding timestamp of the jₙ^{th} dependency representation in sub-bitstream n
   tdₙ(jₙ) may differ from at least one tdₘ(jₘ) in the same access unit Aₙ(j)
tpₙ(jₙ)=presentation timestamp of the jₙ^{th} dependency representation in sub-bitstream n
   tpₙ(jₙ) may differ from at least one tpₘ(jₘ) in the same access unit Aₙ(j)
trefₙ(Jₙ)=timestamp reference to lower (directly referenced) sub-bitstream of the jₙ^{th}
   Dependency representation in sub-bitstream n, where tref trefₙ(jₙ) is
   carried in addition to tdₙ(jₙ) is in the PES packet e.g. in the SVC Dependency Representation delimiter NAL

The received transport stream 300 is processed as follows.

All dependency representations DR_{z}(j_{z}) starting with the highest value, z=n, in the receiving order jₙ of DRₙ(jₙ) in sub-stream n. That is, the sub-streams are de-multiplexed by de-multiplexer 4, as indicated by the individual PID numbers. The content of the data portions received is stored in the DRBs of the individual buffer chains of the different sub-bitstreams. The data of the DRBs is extracted in the order of z to create the jₙ^{th} access unit Aₙ(jₙ) of the sub-stream n according to the following rule:

For the following, it is assumed that the sub-bitstream y is a sub-bitstream having a higher DID than sub-bitstream x. That is, the information in sub-bitstream y depends on the information in sub-bitstream x. For each two corresponding DRₓ(jₓ) and DR_{y}(j_{y}), tref_{y}(j_{y}) is equal tdₓ(jₓ). Applying this teaching to the MPEG 2 transport stream standard, this could, for example, be achieved as follows:

The association information tref may be indicated by adding a field in the PES header extension, which may also be used by future scalable/multi-view coding standards. For the respective field to be evaluated, both the PES_extension_flag and the PES_extension_flag_2 may be set to unity and the stream_id_extension_flag may be set to 0. The association information t_ref could be signaled by using the reserved bit of the PES extension section.

One may further decide to define an additional PES extension type, which would also provide for future extensions.

According to a further embodiment, an additional data field for the association information may be added to the SVC dependency representation delimiter. Then, a signaling bit may be introduced to indicate the presence of the new field within the SVC dependency representation. Such an additional bit may, for example, be introduced in the SVC descriptor or in the Hierarchy descriptor.

According to one embodiment extension of the PES packet header may be implemented by using the existing flags as follows or by introducing the following additional flags:
TimeStampReference_flag—This is a 1-bit flag, when set to ‘1’ indicating the presence of.
PTS_DTS_reference flag—This is a 1-bit flag.
PTR_DTR_flags—This is a 2-bit field. When the PTR_DTR_flags field is set to ‘10’, the following PTR fields contain a reference to a PTS field in another SVC video sub-bitstream or the AVC base layer with the next lower value of NAL unit header syntax element
   dependency_ID as present in the SVC video sub-bitstream containing this extension within the PES header. When the PTR_DTR_flags field is set to ‘01’ the following DTR fields contain a reference to a DTS field in another SVC video sub-bitstream or the AVC base layer with the next lower value of NAL unit header syntax element dependency_ID as present in the SVC video sub-bitstream containing this extension within the PES header. When the PTR_DTR_flags field is set to ‘00’ no PTS or DTS references shall be present in the PES packet header. The value ‘11’ is forbidden.
PTR (presentation time reference)—This is a 33-bit number coded in three separate fields. This is a reference to a PTS field in another SVC video sub-bitstream or the AVC base layer with the next lower value of NAL unit header syntax element dependency_ID as present in the SVC video sub-bitstream containing this extension within the PES header.
DTR (presentation time reference) This is a 33-bit number coded in three separate fields. This is a reference to a DTS field in another SVC video sub-bitstream or the AVC base layer with the next lower value of NAL unit header syntax element dependency_ID as present in the SVC video sub-bitstream containing this extension within the PES header.

An example of a corresponding syntax utilizing the existing and further additional data flags is given in FIG. 7.

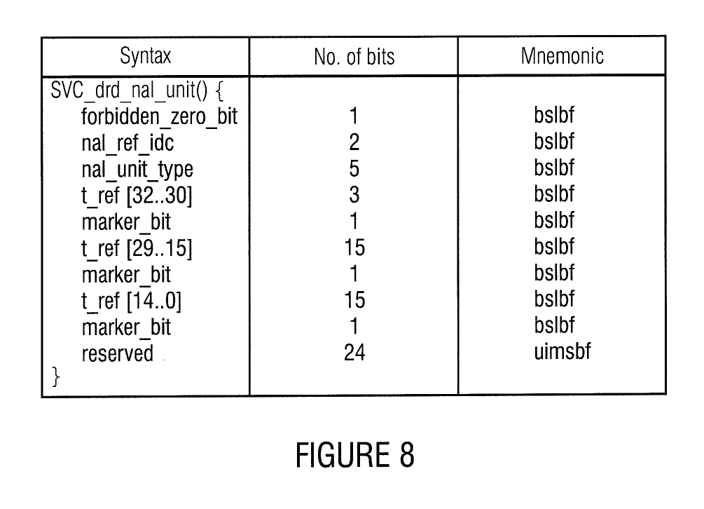

An example for a syntax, which can be used when implementing the previously described second option, is given in FIG. 8. In order to implement the additional association information, the following syntax elements may be attributed the following numbers or values:

Semantics of SVC dependency representation delimiter nal unit
forbidden_zero-bit—shall be equal to 0x00
nal_ref_idc—shall be equal to 0x00
nal_unit_type—shall be equal to 0x18
t_ref[32 . . . 0]—shall be equal to the decoding timestamp DTS as if indicated in the PES header for the
   dependency representation with the next lower value of NAL unit header syntax element
   dependency_id of the same access unit in a SVC video-subbitstream or the AVC base layer. Where the t_ref is set as follows with respect to the DTS of the referenced
   dependency representation: DTS[14 . . . 0] is equal to t_ref[14 . . . 0], DTS [29 . . . 15] is equal to t_ref[29 . . . 15], and DTS[32 . . . 30] is equal to t_ref[32 . . . 30].
maker_bit—is a 1-bit field and shall be equal to “1”.

Further embodiments of the present invention may be implemented as dedicated hardware or in hardware circuitry.

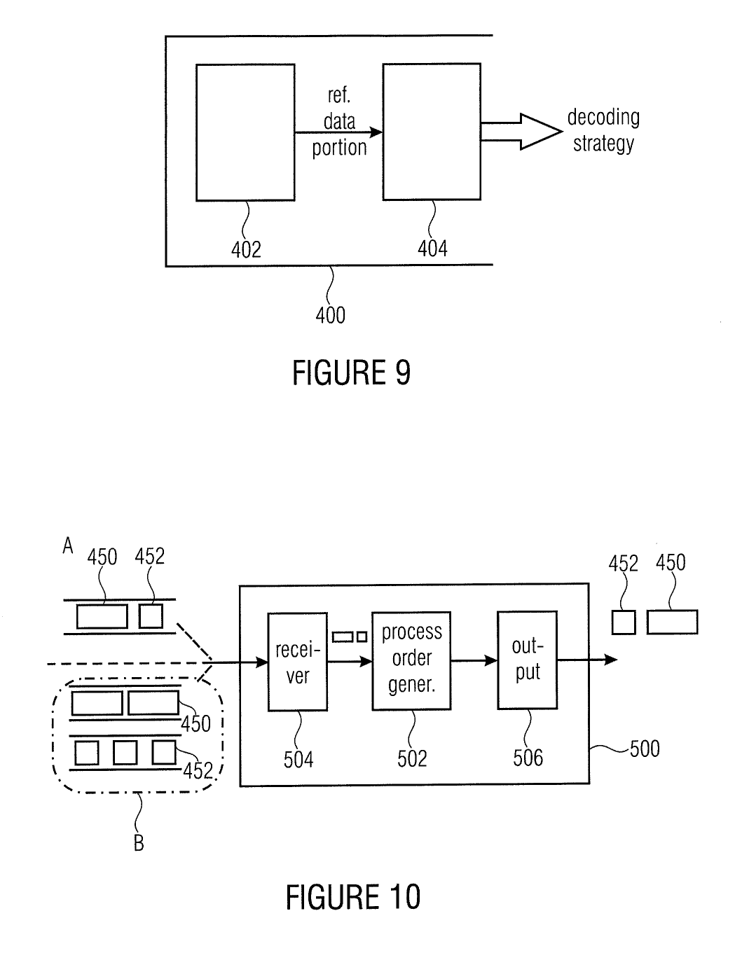

FIG. 9, for example, shows a decoding strategy generator for a second data portion depending on a reference data portion, the second data portion being part of a second data stream of a transport stream comprising a first and a second data stream, wherein the first data portions of the first data stream comprise first timing information and wherein the second data portion of the second data stream comprise second timing information as well as association information indicating a predetermined first data portion of the first data stream.

The decoding strategy generator 400 comprises a reference information generator 402 as well as a strategy generator 404. The reference information generator 402 is adapted to derive the reference data portion for the second data portion using the referenced predetermined first data portion of the first data stream. The strategy generator 404 is adapted to derive the decoding strategy for the second data portion using the second timing information as the indication for a processing time for the second data portion and the reference data portion derived by the reference information generator 402.

According to a further embodiment of the present invention, a video decoder includes a decoding strategy generator as illustrated in FIG. 9 in order to create a decoding order strategy for video data portions contained within data packets of different data streams associated to different levels of a scalable video codec.

The embodiments of the present invention, therefore, allow to create an efficiently coded video stream comprising information on different qualities of an encoded video stream. Due to the flexible referencing, a significant amount of bit rate can be preserved, since redundant transmission of information within the individual layers can be avoided.

The application of the flexible referencing within between different data portions of different data streams is not only useful in the context of video coding. In general, it may be applied to any kind of data packets of different data streams.

FIG. 10 shows an embodiment of a data packet scheduler 500 comprising a process order generator 502, an optional receiver 504 and an optional reorderer 506. The receiver is adapted to receive a transport stream comprising a first data stream and a second data stream having first and second data portions, wherein the first data portion comprises first timing information and wherein the second data portion comprises second timing information and association information.

The process order generator 502 is adapted to generate a processing schedule having a processing order, such that the second data portion is processed after the referenced first data portion of the first data stream. The reorderer 506 is adapted to output the second data portion 452 after the first data portion 450.

As furthermore illustrated in FIG. 10, the first and second data streams do not necessarily have to be contained within one multiplexed transport data stream, as indicated as Option A. To the contrary, it is also possible to transmit the first and second data streams as separate data streams, as it is indicated by option B of FIG. 10.

Multiple transmission and data stream scenarios may be enhanced by the flexible referencing introduced in the previous paragraphs. Further application scenarios are given by the following paragraphs.

A media stream, with scalable, or multi view, or multi description, or any other property, which allows splitting the media into logical subsets, is transferred over different channels or stored in different storage containers. Splitting the media stream may also need to split individual media frames or access unit which are needed as a whole for decoding into subparts. For recovering the decoding order of the frames or access units after transmission over different channels or storage in different storage containers, a process for decoding order recovery is needed, since relying on the transmission order in the different channels or the storage order in different storage containers may not allow recovering the decoding order of the complete media stream or any independently usable subset of the complete media stream. A subset of the complete media stream is built out of particular subparts of access units to new access units of the media stream subset. Media stream subsets may need different decoding and presentation timestamps per frame/access unit depending on the number of subsets of the media stream used for recovering access units. Some channels provide decoding and/or presentation timestamps in the channels, which may be used for recovering decoding order. Additionally channels typically provide the decoding order within the channel by the transmission or storage order or by additional means. For re-covering the decoding order between the different channels or the different storage containers additional information is needed. For at least one transmission channel or storage container, the decoding order is derivable by any means. Decoding order of the other channels are then given by the derivable decoding order plus values indicating for a frame/access unit or subparts thereof in the different transmission channels or storage containers the corresponding frames/access units or subparts thereof in the transmission channel or storage container which for the decoding order is derivable. Pointers may be decoding timestamps or presentation timestamps, but may be also sequence numbers indicating transmission or storage order in a particular channel or container or may be any other indicators which allow identifying a frame/access unit in the media stream subset which for the decoding order is derivable.

A media stream can be split into media stream subsets and is transported over different transmission channels or stored in different storage containers, i.e. complete media frames/media access units or subparts thereof are present in the different channels or the different storage containers. Combining subparts of the frames/access units of the media stream results into decode-able subsets of the media stream.

At least in one transmission channel or storage container, the media is carried or stored in decoding order or in at least one transmission channel or storage container the decoding order is derivable by any other means.

At least, the channel for which the decoding order can be recovered provides at least one indicator, which can be used for identifying a particular frame/access unit or subpart thereof. This indicator is assigned to frames/access units or subparts thereof in at least one other channel or container than the one, which for the decoding order, is derivable.

Decoding order of frames/access units or subparts thereof in any other channel or container than the one which for the decoding order is derivable is given by identifiers which allow finding corresponding frames/access units or subparts thereof in the channel or the container which for the decoding order. The respective decoding order is than given by the referenced decoding order in the channel, which for the decoding order is derivable.

Decoding and/or presentation timestamps may be used as indicator.

Exclusively or additionally view indicators of a multi view coding media stream may be used as indicator.

Exclusively or additionally indicators indicating a partition of a multi description coding media stream may be used as indicator.

When timestamps are used as indicator, the timestamps of the highest level are used for updating the timestamps present in lower subparts of the frame/access unit for the whole access unit.

Although the previously described embodiments mostly relate to video coding and video transmission, the flexible referencing is not limited to video applications. To the contrary, all other packetized transmission applications may strongly benefit from the application of decoding strategies and encoding strategies as previously described, as for example audio streaming applications using audio streams of different quality or other multi-stream applications.

It goes without saying that the application is not depending on the chosen transmission channels. Any type of transmission channels can be used, such as, for example, over-the-air transmission, cable transmission, fiber transmission, broadcasting via satellite, and the like. Moreover, different data streams may be provided by different transmission channels. For example, the base channel of a stream requiring only limited bandwidth may be transmitted via a GSM network, whereas only those who have a UMTS cellular phone ready may be able to receive the enhancement layer requiring a higher bit rate.

Depending on certain implementation requirements of the inventive methods, the inventive methods can be implemented in hardware or in software. The implementation can be performed using a digital storage medium, in particular a disk, DVD or a CD having electronically readable control signals stored thereon, which cooperate with a programmable computer system such that the inventive methods are performed. Generally, the present invention is, therefore, a computer program product with a program code stored on a machine readable carrier, the program code being operative for performing the inventive methods when the computer program product runs on a computer. In other words, the inventive methods are, therefore, a computer program having a program code for performing at least one of the inventive methods when the computer program runs on a computer.

While the foregoing has been particularly shown and described with reference to particular embodiments thereof, it will be understood by those skilled in the art that various other changes in the form and details may be made without departing from the spirit and scope thereof. It is to be understood that various changes may be made in adapting to different embodiments without departing from the broader concepts disclosed herein and comprehended by the claims that follow.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. Method for deriving a decoding strategy for a second data portion depending on a reference data portion, the second data portion being part of a second data stream of a transport stream, the transport stream comprising the second data stream and a first data stream comprising first data portions, the first data portions comprising first timing information and the second data portion of the second data stream comprising second timing information and association information indicating a predetermined first data portion of the first data stream, comprising:
deriving the decoding strategy for the second data portion using the second timing information as an indication for a processing time for the second data portion and the referenced predetermined first data portion of the first data stream as the reference data portion.

2. Method according to claim 1, in which the association information of the second data portion is the first timing information of the predetermined first data portion.

3. Method according to claim 1 or 2, further comprising:
processing the first data portion before the second data portion.

4. Method according to claims 1 to 3, further comprising:
outputting the first and the second data portions, wherein the referenced predetermined first data portion is output prior to the second data portion.

5. Method according to claim 4, wherein the output first and second data portions are provided to a decoder.

6. Method according to claims 1 to 5, wherein second data portions comprising the association information in addition to the second timing information are processed.

7. Method according to claims 1 to 6, wherein second data portions having association information differing from the second timing information are processed.

8. Method according to any of the previous claims, wherein the dependency of the second data portion is such, that a decoding of the second data portion requires information contained within the first data portion.

9. Method according to any of the previous claims, in which the first data portions of the first data stream are associated to encoded video frames of a first layer of a layered video data stream; and
in which the data portion of the second data stream is associated to an encoded video frame of a second, higher layer of the scalable video data stream.

10. Method according to claim 9, in which the first data portions of the first data stream are associated to one or more NAL-units of a scalable video data stream; and
in which the data portion of the second data stream is associated to one or more second, different NAL-units of the scalable video data stream.

11. Method according to any of claim 9 or 10, in which the second data portion is associated with the predetermined first data portion using a decoding time stamp of the predetermined first data portion as the association information, the decoding time stamp indicating a processing time of the predetermined first data portion within the first layer of the scalable video data stream.

12. Method according to any of claims 9 to 11, in which the second data portion is associated with the first predetermined data portion using a presentation time stamp of the first predetermined data portion as the association information, the presentation time stamp indicating a presentation time of the first predetermined data portion within the first layer of the scalable video data stream.

13. Method according to any of claims 11 or 12, further using a view information indicating one of possible different views within the scalable video data stream or a partition information indicating one of different possible partitions of a multi-description coding media stream of the first data portion as the association information.

14. Method according to any of the previous claims, further comprising:
evaluating mode data associated to the second data stream, the mode data indicating a decoding strategy mode for the second data stream, wherein
if a first mode is indicated, the decoding strategy is derived in accordance to any of claims 1 to 8; and
if a second mode is indicated, the decoding strategy for the second data portion is derived using the second timing information as a processing time for the processed second data portion and a first data portion of the first data stream having a first timing information identical to the second timing information as the reference data portion.

15. Video data representation, comprising:
a transport stream comprising a first and a second data stream, wherein
first data portions of the first data stream comprise first timing information; and
a second data portion of the second data stream comprises second timing information and association information indicating a predetermined first data portion of the first data stream.

16. Video data representation according to claim 15, further comprising mode data associated to the second data stream, the mode data indicating a selected out of at least two decoding strategy modes for the second data stream.

17. Video data representation according to claim 15 or 16, wherein the first timing information of the predetermined first data portion is used as the association information of the second data portion.

18. Method for generating a representation of a video sequence, the video sequence comprising a first data stream comprising first data portions, the first data portions comprising first timing information and a second data stream, the second data stream comprising a second data portion having second timing information, comprising:
associating association information to a second data portion of the second data stream, the association information indicating a predetermined first data portion of the first data stream; and
generating a transport stream comprising the first and the second data stream as the representation of the video sequence.

19. Method for generating a representation of a video sequence according to claim 18, in which the association information is introduced as an additional data field into the second data portion.

20. Method for generating a representation of a video sequence according to claim 18, in which the association information is introduced in an existing data field of the second data portion.

21. Method for generating a representation of a video sequence according to any of claims 18 to 20, further comprising:
associating mode data to the second data stream, the mode data indicating a decoding strategy mode out of at least two possible decoding strategy modes for the second data stream.

22. Method for generating a representation of a video sequence according to claim 21, wherein the mode data is introduced as an additional data field into the second data portion of the second data stream.

23. Method for generating a representation of a video sequence according to claim 21, in which the association information is introduced in an existing data field of the second data portion of the second data stream.

24. Decoding strategy generator for a second data portion depending on a reference data portion, the second data portion being part of a second data stream of a transport stream, the transport stream comprising the second data stream and a first data stream comprising first data portions, the first data portions comprising first timing information and the second data portion of the second data stream comprising second timing information and association information indicating a predetermined first data portion of the first data stream, comprising:
a reference information generator adapted to derive the reference data portion for the second data portion using the predetermined first data portion of the first data stream; and
a strategy generator adapted to derive the decoding strategy for the second data portion using the second timing information as indication for a processing time for the second data portion and the reference data portion derived by the reference information generator.

25. Video representation generator adapted to generate a representation of a video sequence, the video sequence comprising a first data stream comprising first data portions, the first data portions comprising first timing information and a second data stream, the second data stream comprising a second data portion having second timing information, comprising:
a reference information generator adapted to associating association information to the second data portion of the second data stream, the association information indicating a predetermined first data portion of the first data stream; and
a multiplexer adapted to generate a transport stream comprising the first and the second data stream and the association information as the representation of the video sequence.

26. Method for deriving a processing schedule for a second data portion depending on a reference data portion, the second data portion being part of a second data stream of a transport stream, the transport stream comprising the second data stream and a first data stream comprising first data portions, the first data portions comprising first timing information and the second data portion of the second data stream comprising second timing information and association information indicating a predetermined first data portion of the first data stream, comprising:
deriving the processing schedule having a processing order such that the second data portion is processed after the predetermined first data portion of the first data stream.

27. Method for deriving a processing schedule according to claim 26, further comprising:
receiving the first and second data portions; and
appending the second data portion to the first data portion in an output bitstream.

28. Data packet scheduler, adapted to generate a processing schedule for a second data portion depending on a reference data portion, the second data portion being part of a second data stream of a transport stream, the transport stream comprising the second data stream and a first data stream comprising first data portions, the first data portions comprising first timing information and the second data portion of the second data stream comprising second timing information and association information indicating a predetermined first data portion of the first data stream, comprising:
a process order generator adapted to generate a processing schedule having a processing order such that the second data portion is processed after the predetermined first data portion of the first data stream

29. Data packet scheduler according to claim 28, further comprising:
a receiver adapted to receive the first and second data portions; and
a reorderer adapted to output the second data portion after the first data portion.

30. Computer program having a program code for performing, when running on a computer, a according to any of claims 1, 18, 26.
